(19) United States
(12) Patent Application Publication
(10) Pub. No.: US 2003/0122585 A1
(43) Pub. Date: Jul. 3, 2003

(54) FET/bipolar integrated logic circuits

(76) Inventor: Ramautar Sharma, Berkely Heights, NJ (US)

Correspondence Address: Daniel H. Golub, MORGAN, LEWIS & BOCKIUS LLP, 1701 Market Street, Philadelphia, PA, 19103-2921, US

(21) Appl. No.: 10/039,754

(22) Filed: Jan. 3, 2002

(51) Int. Cl. H03K 19/094

(52) U.S. Cl. 326/109

(57) ABSTRACT

An inverter circuit that includes a FET input transistor having a gate, a source, a drain and a FET output transistor having a gate, a source and a drain. The circuit further includes first and second power lines and a constant current source. No transistor other than the input and output transistors is coupled between the input and output terminals. Also, a Bipolar inverter circuit, a FET NAND/AND function circuit, a Bipolar NAND/AND function circuit, a FET differential circuit and a Bipolar differential circuit using the inverter circuit as a building block.

### FIELD OF THE INVENTION

This invention relates to integrated circuits, and more particularly to FET/Bipolar integrated logic circuits.

### BACKGROUND OF THE INVENTION

FET/Bipolar static logic is widely used because of its high packing densities, noise margins, and operating frequencies. There is a trend in the industry towards mixed-mode monolithic systems containing higher frequency and higher accuracy analog circuitry combined with increasingly complex digital circuitry which increases power dissipation. The achievable accuracy of many such systems is now limited by the frequency performance of the conventional FET/Bipolar static logic circuitry. It would be beneficial to provide a FET/Bipolar integrated logic circuit formed using a minimal number of components and having enhanced frequency performance, accuracy and reduced power dissipation.

### SUMMARY OF THE INVENTION

The present invention provides a first preferred embodiment of an integrated inverter circuit. The first embodiment comprises a FET input transistor having a gate, a source, a drain and a FET output transistor having a gate, a source and a drain. The circuit further comprises first and second power lines and a constant current source. The sources of the input and output transistors are coupled to the second power line and the gate of the input transistor is connected to a digital input terminal. The gate of the output transistor is connected to the drain of the input transistor and the drain of the output transistor is connected to a digital output terminal. The drain of the input transistor is coupled to the constant current source through the first power line and the drain of the input transistor is connected to the digital input terminal. No transistor other than the input and output transistors is coupled between the input and output terminals.

The present invention further provides a second preferred embodiment of an integrated inverter circuit. The second embodiment comprises a Bipolar input transistor having a base, an emitter, a collector and a Bipolar output transistor having a base, an emitter and a collector. The circuit also comprises first and second power lines and a constant current source. The emitters of the input and output transistors are coupled to the second power line and the base of the input transistor is connected to a digital input terminal. The base of the output transistor is connected to the collector of the input transistor and the collector of the output transistor is connected to a digital output terminal. The collector of the input transistor is coupled to the first power line through the constant current source and the collector of the input transistor is connected to the digital input terminal. No transistor other than the input and output transistors is coupled between is input and output terminals.

The present invention provides a further embodiment of an integrated NAND/AND function circuit. This embodiment comprises first, second and third integrated sub circuits. The first, second and third integrated sub circuits have first and second power lines. The first integrated sub circuit comprises a first FET input transistor having a first gate, a first source and a first drain and a second FET output transistor having a second gate, a second source and a second drain. The first integrated sub circuit further comprises a first constant current source. The first gate is connected to a digital input terminal iᵢₙ₁. The second gate is connected to the first drain. The second drain is connected to a digital output terminal iₒᵤₜ₁. The first drain is coupled to the first constant current source through the first power line. The first drain is connected to the digital input terminal iᵢₙ₁. The second integrated sub circuit comprises a third FET input transistor having a third gate, a third source and a third drain and a fourth FET output transistor having a fourth gate, a fourth source and a fourth drain. The second integrated sub circuit further comprises a second constant current source. The third gate is connected to a digital input terminal iᵢₙ₂ and the fourth gate is connected to the third drain. The fourth drain is connected to a digital output terminal iₒᵤₜ₂ and the third drain is coupled to the second constant current source through the first power line. The third drain is connected to the digital input terminal iᵢₙ₂. The third integrated sub circuit comprises a fifth FET input transistor having a fifth gate, a fifth source and a fifth drain and a sixth FET output transistor having a sixth gate, a sixth source and a sixth drain. The third integrated sub circuit further comprises a third constant current source. The first, second, third, fourth, fifth and sixth sources are coupled to the second power line. The fifth gate is connected to a digital output terminal i_{out1, 2}. The sixth gate is connected to the fifth drain and the sixth drain is connected to a digital output terminal iₒᵤₜ. The fifth drain is coupled to the third constant current source through the first power line. The fifth drain is connected to the digital output terminal i_{out1, 2}. The digital output terminal i_{out1, 2} is connected to digital output terminal iₒᵤₜ₁. The digital output terminal i_{out1, 2} is connected to digital output terminal iₒᵤₜ₂. No transistor, other than said first input and second output transistors, is coupled between said input terminal iᵢₙ₁ and output terminal iₒᵤₜ₁. No transistor, other than said third input and fourth output transistors, is coupled between said input terminal iᵢₙ₂ and output terminal iₒᵤₜ₂. No transistor other than said fifth input and sixth output transistors is coupled between said output terminal i_{out1, 2} and output terminal iₒᵤₜ. Individual currents at terminals iᵢₙ₁, iᵢₙ₂, iₒᵤₜ₁ and iₒᵤₜ₂ are logically related to a current at terminal i_{out1, 2} in accordance with a NAND function. Individual currents at terminals iᵢₙ₁, iᵢₙ₂, iₒᵤₜ₁ and iₒᵤₜ₂ are logically related to a current at terminal iₒᵤₜ in accordance with an AND function.

The present invention provides a further embodiment of an integrated NAND/AND function circuit. This embodiment comprises first, second and third integrated sub circuits. The first, second and third integrated sub circuits have first and second power lines. The first integrated sub circuit comprises a first Bipolar input transistor having a first base, a first emitter and a first collector and a second Bipolar output transistor having a second base, a second emitter and a second collector. The circuit also comprises a first constant current source. The first base is connected to a digital input terminal iᵢₙ₁ and the second base is connected to the first collector. The second collector is connected to a digital output terminal iₒᵤₜ₁ and the first collector is coupled to the first constant current source through the first power line. The first collector is connected to the digital input terminal iᵢₙ₁. The second integrated sub circuit comprises a third Bipolar input transistor having a third base, a third emitter and a third collector and a fourth Bipolar output transistor having a fourth base, a fourth emitter and a fourth collector. The circuit further comprises a second constant current source. The third base is connected to a digital input terminal iᵢₙ₂ and the fourth base is connected to the third collector. The fourth collector is connected to a digital output terminal iₒᵤₜ₂ and the third collector is coupled to the second constant current source through the first power line. The third collector is connected to the digital input terminal iᵢₙ₂. The third integrated sub circuit comprises a fifth Bipolar input transistor having a fifth base, a fifth emitter and a fifth collector and a sixth Bipolar output transistor having a sixth base, a sixth emitter and a sixth collector. The circuit further comprises a third constant current source. The first, second, third, fourth, fifth and sixth emitters being coupled to the second power line. The fifth base is connected to a digital output terminal I_{out1, 2} and the sixth base is connected to the fifth collector. The sixth collector is connected to a digital output terminal iₒᵤₜ and the fifth collector is coupled to the third constant current source through the first power line. The fifth collector is connected to the digital output terminal i_{out1, 2}. The digital output terminal i_{out1, 2} is connected to digital output terminal iₒᵤₜ₁. The digital output terminal i_{out1, 2} is connected to digital output terminal iₒᵤₜ₂. No transistor, other than said first input and second output transistors is coupled between said input terminal iᵢₙ₁ and output terminal iₒᵤₜ₁. No transistor, other than said third input and fourth output transistors is coupled between said input terminal iᵢₙ₂ and output terminal iₒᵤₜ₂. No transistor other than said fifth input and sixth output transistors is coupled between said output terminal i_{out1, 2} and output terminal iₒᵤₜ. Individual currents at terminals iᵢₙ₁, iᵢₙ₂, iₒᵤₜ₁ and iₒᵤₜ₂ are logically related to a current at terminal iₒᵤₜ₂ in accordance with a NAND function. Individual currents at terminals iᵢₙ₁, iᵢₙ₂, iₒᵤₜ₁ and iₒᵤₜ₂ are logically related to a current at terminal iₒᵤₜ in accordance with an AND function.

The present invention provides a further embodiment of an integrated differential circuit. This embodiment comprises first and second integrated sub circuits. The first and second integrated sub circuits having first and second power lines. The first integrated sub circuit comprises a first FET transistor having a first gate, a first source and a first drain and a second FET transistor having a second gate, a second source and a second drain. The first integrated sub circuit further comprises first and second constant current sources. The first and second sources are coupled to the first constant current source through the second power line. The first gate is connected to a first digital input terminal and the second gate is connected to the first drain. The second drain is connected to a first digital output terminal and the first drain is coupled to the second constant current source through the first power line. The first drain is connected to the first digital input terminal. The second integrated sub circuit comprises a third FET transistor having a third gate, a third source and a third drain and a fourth FET transistor having a fourth gate, a fourth source and a fourth drain. The second integrated circuit further comprises a third constant current source. The third and fourth sources coupled to the first constant current source through the second power line. The third gate is connected to a second digital input terminal and the fourth gate is connected to the third drain. The fourth drain is connected to a second digital output terminal and the third drain is coupled to the third constant current source through the first power line. The third drain is connected to the second digital input terminal. A fifth FET transistor comprises the second constant current source. A sixth FET transistor comprises the third constant current source. No transistor other than the first and second transistors is coupled between said first input terminal and the first output terminal. No transistor other than the third and fourth transistors is coupled between said second input terminal and the second output terminal.

The present invention provides a further embodiment of an integrated differential circuit. This embodiment comprises first and second integrated sub circuits. The first and second integrated sub circuits having first and second power lines. The first integrated sub circuit comprises a first Bipolar transistor having a first base, a first emitter and a first collector and a second Bipolar transistor having a second base, a second emitter and a second collector. The first integrated sub circuit further comprises first and second constant current sources. The first and second emitters are coupled to the first constant current source through the second power line. The first base is connected to a first digital input terminal and the second base is connected to the first collector. The second collector is connected to a first digital output terminal and the first collector is coupled to the second constant current source through the first power line. The first collector is connected to the first digital input terminal. The second integrated sub circuit comprises a third Bipolar transistor having a third base, a third emitter and a third collector and a fourth Bipolar transistor having a fourth base, a fourth emitter and a fourth collector. The second integrated sub circuit includes a third constant current source. The third and fourth emitters coupled to the first constant current source through the second power line. The third base is connected to a second digital input terminal and the fourth base is connected to the third collector. The fourth collector is connected to a second digital output terminal and the third collector is coupled to the third constant current source through the first power line. The third collector is connected to the second digital input terminal. A fifth Bipolar transistor comprises the second constant current source and a sixth Bipolar transistor comprises the third constant current source. No transistor other than the first and second transistors is coupled between said first input terminal and the first output terminal. No transistor other than the third and fourth transistors is coupled between the second input terminal and the second output terminal.

### BRIEF DESCRIPTION OF THE DRAWINGS

The accompanying drawings, which are incorporated herein and constitute part of the specification, illustrate presently preferred embodiments of the invention, and, together with the general description given above and detailed description given below, serve to explain features of the invention. In the Figures:

FIG. 1A shows a schematic diagram of an FET inverter circuit;

FIG. 1B shows a schematic diagram of a merged transistor configuration FET circuit;

FIG. 2 is a chart showing delay time dependence on bias current for the circuits of FIG.'s 1A and 1B;

FIG. 3 is a chart showing the frequency operation dependence on bias current for the circuits of FIG.'s 1A and 1B;

FIG. 4 shows a schematic diagram of a FET inverter circuit with a Fan Out=3;

FIG. 5 shows a schematic diagram of a Bipolar inverter circuit with a Fan Out=3;

FIG. 6 shows a schematic diagram of a Bipolar inverter circuit;

FIG. 7 shows a schematic diagram of a FET NAND/AND function circuit;

FIG. 8 is a chart showing the function of a 2-Input mode NAND function circuit;

FIG. 9 shows a schematic diagram of a Bipolar NAND/AND function circuit;

FIG. 10 shows a schematic diagram of a FET differential circuit;

FIG. 11 is a chart showing the function of a differential circuit; and

FIG. 12 shows a schematic diagram of a FET differential circuit.

### DETAILED DESCRIPTION OF THE INVENTION

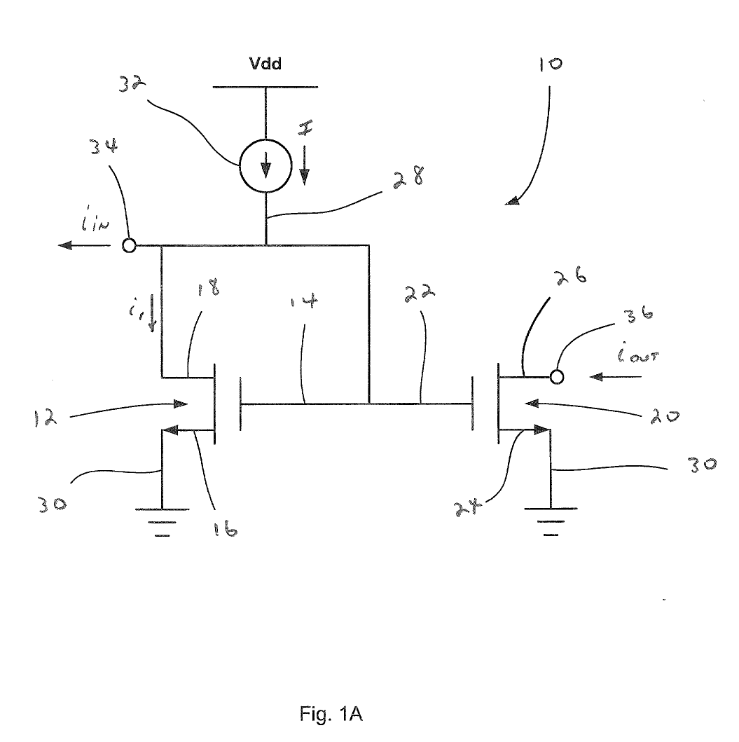

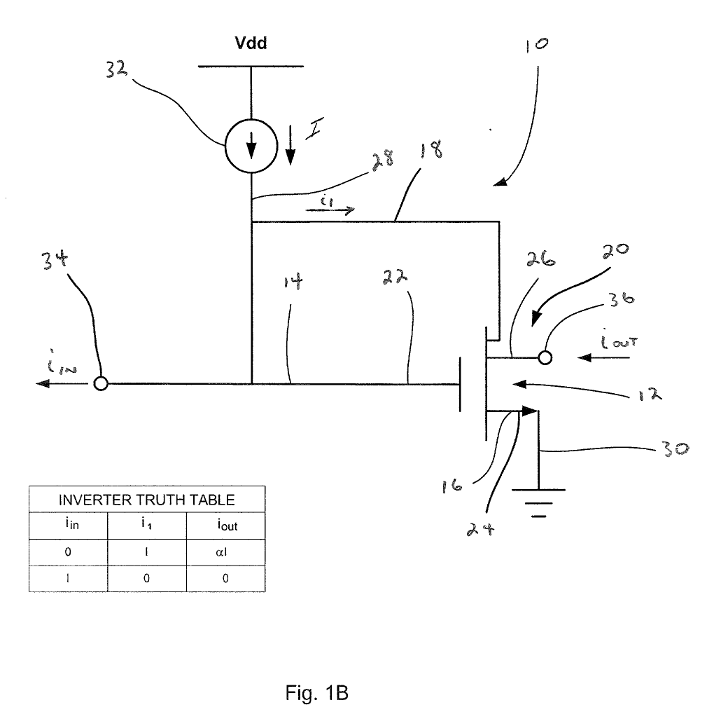

There is shown in FIG. 1A, a schematic diagram of a first preferred embodiment of an integrated inverter circuit 10. The inverter circuit 10 comprises a diode connected FET input transistor 12. (A FET transistor having its gate and drain terminal connected together is considered diode connected.) The FET input transistor 12 has a gate 14, a source 16 and a drain 18. The inverter circuit 10 further comprises a FET output transistor 20. The FET output transistor 20 has a gate 22, a source 24 and a drain 26. The inverter circuit 10 includes a first power line 28, a second power line 30 and a constant current source 32.

Sources 16 and 24 are coupled to the second power line 30. Gate 14 is connected to a digital input terminal 34. Gate 22 is connected to drain 18. Drain 26 is connected to a digital output terminal 36. Drain 18 is connected to the constant current source 32 through the first power line 28. Drain 18 is further connected to the digital input terminal 34. No transistor, other than the input transistor 12 and output transistor 20, is coupled between digital input terminal 34 and digital output terminal 36.

The operation of inverter circuit 10 is based on the summation of the node currents at input terminal 34. The state of the summation of node currents at input terminal 34 is determined by the state of the currents that flow through the devices of the inverter circuit 10. The state of the node currents are said to be either at a logic “high” or logic “low” state. Conventional inverter circuits depend on node voltage changes rather than node current changes to achieve their “high” and “low” states.

The inversion of input current takes place at output terminal 36 in accordance with equation (1) below:

i₁=I−iᵢₙ (1)

The current iₒᵤₜ flows through the diode connected input transistor 12. A proportional output current iₒᵤₜ flows into output transistor 20 in accordance with equation (2) below:

iₒᵤₜ=α*i₁ (2)

The proportionality constant α shown in equation (2) is determined by the relative sizes of the input 12 and output 20 transistors. For MOS transistors, the ratio of the Width/Length of transistors determines the constant α. Table I is based on Equations (1) and (2) and describes the logical operation of the inverter circuit 10 as shown in FIG. 1A.

TABLE I
Inverter Truth-Table

| Input Current (iᵢₙ) | Current into Diode (i₁) | Output Current (iₒᵤₜ) |
|---|---|---|
| 0 | I | αI |
| I | 0 | 0 |

During the inversion process, the current that is drawn from the power supply Vdd is constant. The “Low” and “High” states of the input current may not actually be 0A and I, but could be some fraction of I, such as I/n_{Low} and I/n_{High}, respectively. Given the aforementioned currents from equations (1) and (2) and assuming that α=1, the input node (34) voltage change between the logic “High” and logic “Low” state is given by Equation (3) below for inverter circuit 10.

$${V}_{High} - {V}_{Low} = ( \sqrt{\frac{2 I}{β}} ) ( \frac{\sqrt{{n}_{Low}} - \sqrt{{n}_{High}}}{\sqrt{{n}_{High} {n}_{Low}}} \qquad ( 3 )$$

where β=(μCₒₓ) (W/L); μ=electronic carrier mobility, Cₒₓ=gate capacitance per unit area, (W/L)=channel width to length ratio. For example, if β=(280*10⁻⁶) (5/0.72)=1.9 mA/V², and I=1 mA, n_{Low}=9, and n_{High}=4, then the node voltage change is 171 mV. The small change in the node voltage leads to smaller charging and discharging times. Smaller charging and discharging times leads to the increased operating speeds of the transistor. The small voltage change also leads to lower power dissipation within the transistor.

FIG. 1B shows a schematic diagram of the integrated inverter circuit 10 that was described above and shown in FIG. 1A with the exception that the FET input transistor and FET output transistor have been merged together. The function of the integrated inverter circuit 10 has not changed.

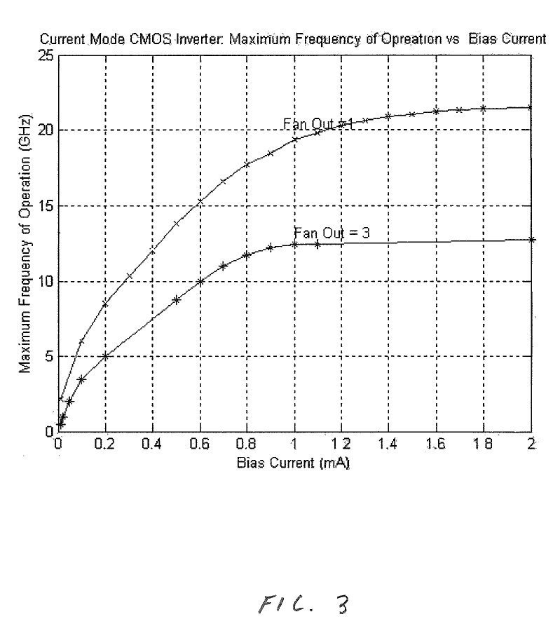

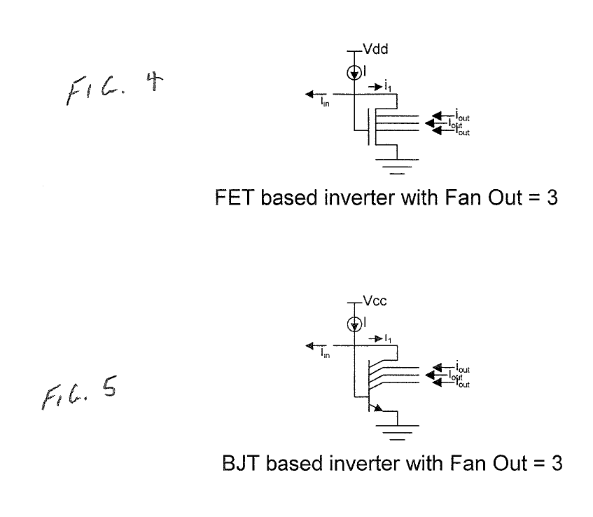

The delay times and the operating frequency dependence versus bias current, I, for an inverter circuit 10 with a Fan Out=1 and a Fan Out=3 are shown in FIG.'s 2 and 3, respectively. The number of Fan Outs corresponds to the number of drains of the FET output transistor, and in the case of a Bipolar inverter, the number of Fan Outs corresponds to the number of collectors of the Bipolar output transistor. A FET inverter circuit with a Fan Out=3 is shown in FIG. 4 and a Bipolar inverter circuit with a Fan Out=3 is shown in FIG. 5.

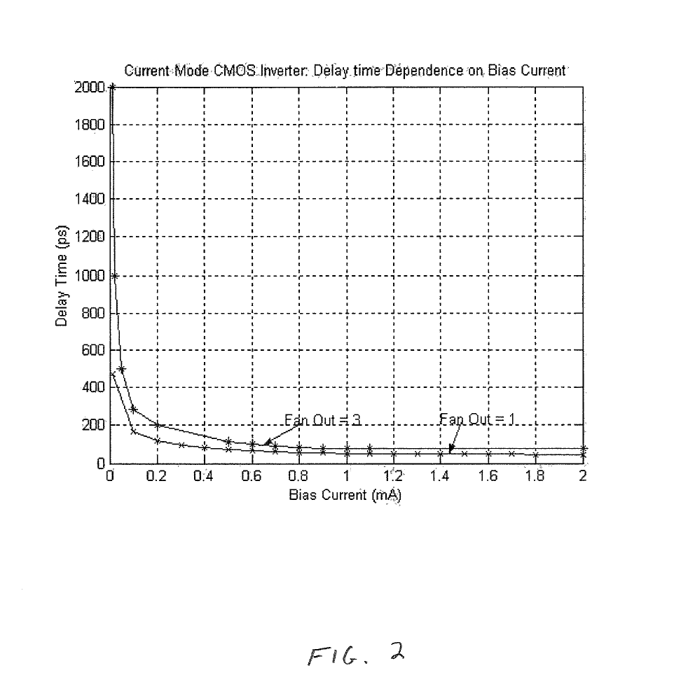

FIG. 3 shows maximum frequency of operation vs. bias current. Note, that for a standard CMOS inverter there is no control on the bias current. The power supply voltage Vdd controls the overall speed of operation. When a standard CMOS transistor is compared with a CMOS transistor of the present invention, wherein both the standard CMOS transistor and the CMOS transistor of the present invention have a similar size of W=2.5 micron and L=0.18 micron and a given power supply of 1.8V, the standard CMOS transistor starts operating incorrectly at input signal frequencies greater than 5 GHz for a Fan Out=1.

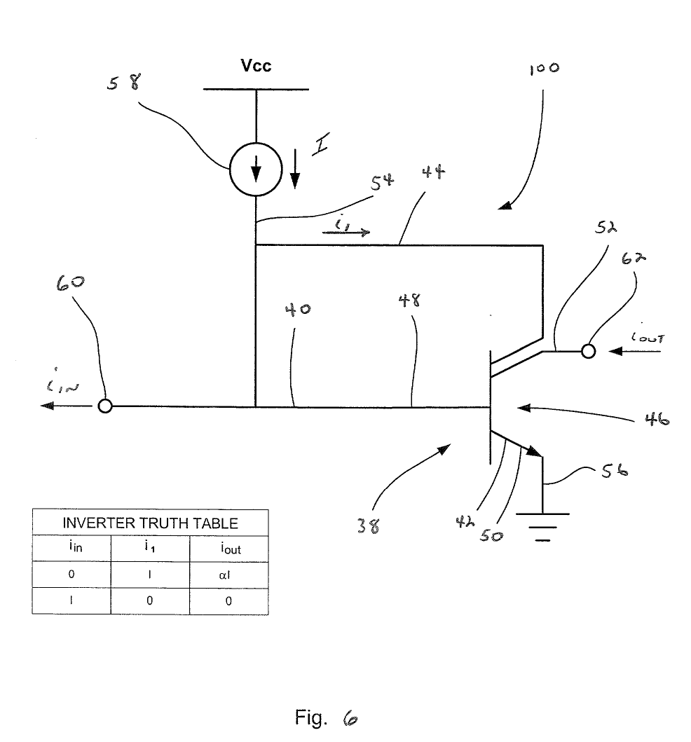

FIG. 6 shows a further embodiment of an integrated inverter circuit 100. The inverter circuit 100 comprises a diode connected Bipolar input transistor 38. (A Bipolar transistor having it's base and collector terminals connected together is considered diode connected.) The Bipolar input transistor 38 has a base 40, an emitter 42 and a collector 44. The inverter circuit 100 further comprises a Bipolar output transistor 46. The Bipolar output transistor 46 has a base 48, an emitter 50 and a collector 52. The inverter circuit 100 includes a first power line 54, a second power line 56 and a constant current source 58. Emitter 42 and emitter 50 are coupled to the second power line 56. Base 40 is connected to a digital input terminal 60. Base 48 is connected to collector 44. Collector 52 is connected to a digital output terminal 62. Collector 44 is coupled to the first power line 54 through the constant current source 58. Collector 44 is connected to the digital input terminal 60. No transistor, other than the input transistor 38 and the output transistor 46, is coupled between the digital input terminal 60 and the digital output terminal 62.

The operation and frequency response of Bipolar inverter circuit 100 is very similar to that of the FET inverter circuit 10. However, in the case of a Bipolar transistor, it is the emitter area ratio that determines the constant α. Given the aforementioned currents from equations (1) and (2) and assuming that α=1, the input node 60 voltage change between the logic “High” and logic “Low” state is given by Equation (4) for a Bipolar transistor.

$${V}_{High} - {V}_{Low} = ( \frac{kT}{q} ) ln ( \frac{{n}_{Low}}{{n}_{High}} ) \qquad ( 4 )$$

Where k=Boltzmann's constant, T=absolute temperature, q=electronic charge. If the values n_{Low}=9, n_{High}=4, k=1.38×10⁻²³ Joules, T=27 C, and q=1.6×10⁻¹⁹ are applied to Equation (4), then V_{high}−V_{low}=((1.38×10⁻²³*(273+27))/1.6×10 ⁻¹⁹) 1n(9/4)=(0.0259)(0.8019)=21 mV. Thus, for the same current levels, the 21 mV voltage swing of the Bipolar transistor is much smaller than the 171 mV voltage swing for the FET transistor and hence even higher speeds and lower power dissipation may be achieved.

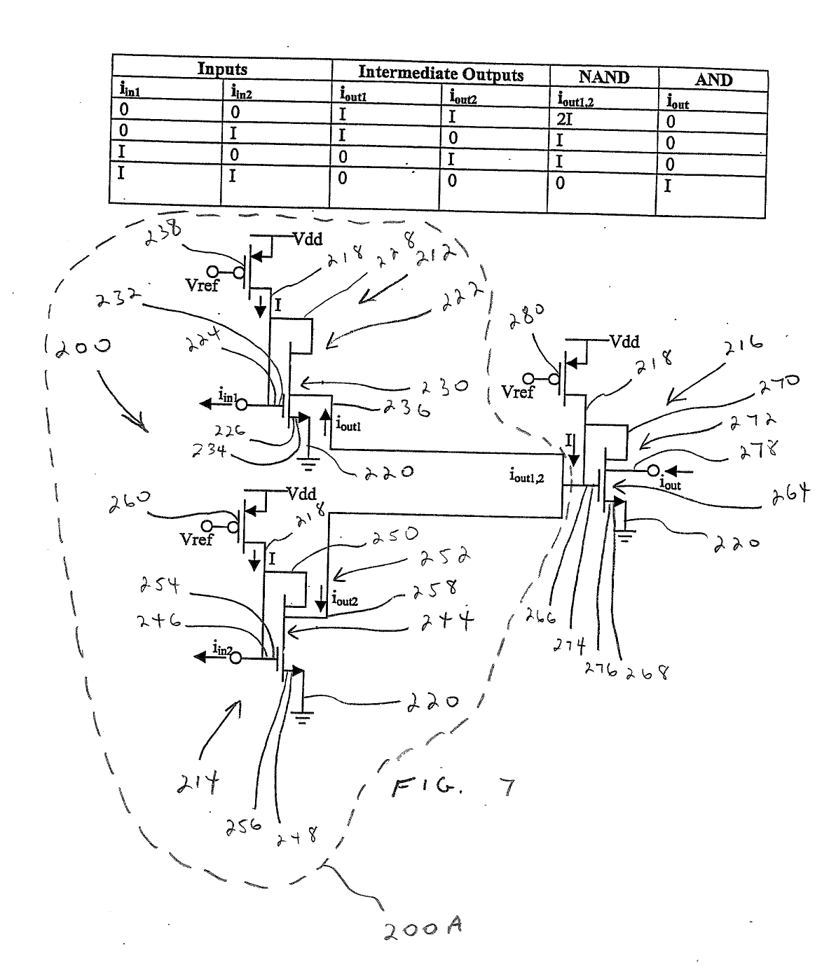

There is shown in FIG. 7, a schematic diagram of a further embodiment of an integrated NAND/AND function circuit 200. The NAND/AND circuit 200 comprises a first integrated sub circuit 212, a second integrated sub circuit 214 and a third integrated sub circuit 216. It should be recognized that the previously described inverter circuit 10 is the basic building block for sub circuits 212, 214 and 216. The first sub circuit 212, second sub circuit 214 and third sub circuit 216 have a first power line 218 and a second power line 220.

The first integrated sub circuit 212 comprises a first FET input transistor 222. The first FET input transistor 222 has a first gate 224, a first source 226 and a first drain 228. The first integrated sub circuit 212 further comprises a second FET output transistor 230. The second FET output transistor 230 has a second gate 232, a second source 234 and a second drain 236. The first integrated sub circuit 212 includes a first constant current source 238. The first gate 224 is connected to a digital input terminal iᵢₙ₁. The second gate 232 is connected to the first drain 228. The second drain 236 is connected to a digital output terminal iₒᵤₜ₁. The first drain 228 is coupled to the first constant current source 238 through the first power line 218. The first drain 228 is connected to the digital input terminal iᵢₙ₁.

The second integrated sub circuit 214 comprises a third FET input transistor 244. The third FET input transistor 244 has a third gate 246, a third source 248 and a third drain 250. The second FET 214 further comprises a fourth FET output transistor 252. The fourth FET output transistor 252 has a fourth gate 254, a fourth source 256 and a fourth drain 258. The second integrated sub circuit 214 includes a second constant current source 260. The third gate 246 is connected to a digital input terminal iᵢₙ₂ and the fourth gate 254 is connected to the third drain 250. The fourth drain 258 is connected to a digital output terminal iₒᵤₜ₂ and the third drain 250 is coupled to the second constant current source 260 through the first power line 218. The third drain 250 is connected to the digital input terminal iᵢₙ₂.

The third integrated sub circuit 216 comprises a fifth FET input transistor 264 having a fifth gate 266, a fifth source 268 and a fifth drain 270. The third integrated sub circuit 216 further comprises a sixth FET output transistor 272 having a sixth gate 274, a sixth source 276 and a sixth drain 278. The third integrated sub circuit 216 includes a third constant current source 280. The first 226, second 234, third 248, fourth 256, fifth 268 and sixth sources 276 are coupled to the second power line 220. The fifth gate 266 is connected to a digital output terminal i_{out1, 2}. The sixth gate 274 is connected to the fifth drain 270 and the sixth drain 278 is connected to a digital output terminal iₒᵤₜ. The fifth drain 270 is coupled to the third constant current source 280 through the first power line 218. The fifth drain 270 is connected to the digital output terminal i_{out1, 2}. The digital output terminal i_{out1, 2} is connected to digital output terminal iₒᵤₜ₁. The digital output terminal i_{out1, 2} is connected to digital output terminal iₒᵤₜ₂.

No transistor, other than the first input transistor 222 and second output transistor 230, is coupled between the input terminal iᵢₙ₁ and output terminal iₒᵤₜ₁. No transistor, other than the third input transistor 244 and fourth output transistor 252, is coupled between said input terminal iᵢₙ₂ and output terminal iₒᵤₜ₂. No transistor other than the fifth input transistor 264 and sixth output transistor 272 is coupled between said output terminal i_{out1, 2} and output terminal iₒᵤₜ. Individual currents at terminals iᵢₙ₁, iᵢₙ₂, iₒᵤₜ₁ and iₒᵤₜ₂ are logically related to a current at terminal i_{out1, 2} in accordance with a NAND function. Individual currents at terminals iᵢₙ₁, iᵢₙ₂, iₒᵤₜ₁ and iₒᵤₜ₂ are logically related to a current at terminal iₒᵤₜ in accordance with an AND function.

Operation of the NAND/AND function circuit 200 will now be described in conjunction with FIG. 7. A NAND function circuit 200A is synthesized by connecting the i_{out1, 2} drains of two FET inverters. In the case of a Bipolar NAND function circuit, the i_{out1, 2} collectors of the inverters are connected together. The output current i_{out1, 2} of the NAND function circuit 200 which is a function of the input currents iᵢₙ₁ and iᵢₙ₂ is shown in Table II below.

TABLE II
2-Input NAND Gate Truth Table

| Input Current i₁ | Input Current i₂ | Output Current i_{out1 2} |
|---|---|---|
| 0 | 0 | 2I |
| 0 | I | I |
| I | 0 | I |
| I | I | 0 |

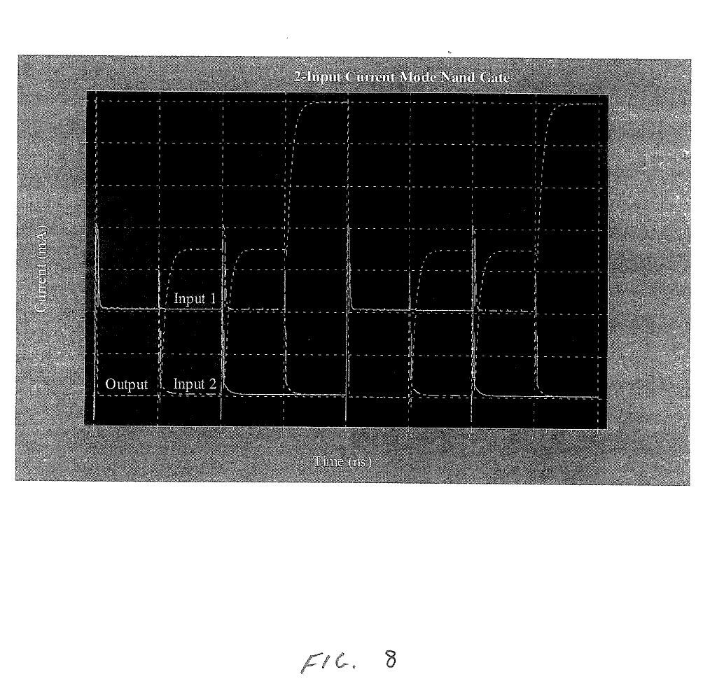

The function of the NAND function circuit is shown in FIG. 8. As was the case with the inverter circuits 10 and 100, the input currents corresponding to logic “Low” and “High” states need not be 0A and I, but can be chosen appropriately to maximize the speed of operation and minimize the power dissipation. By connecting the output of the NAND function circuit 200A to an inverter, a NAND/AND function circuit combination can be realized. A table showing the operation of the combined NAND/AND function circuit is shown with FIG. 7.

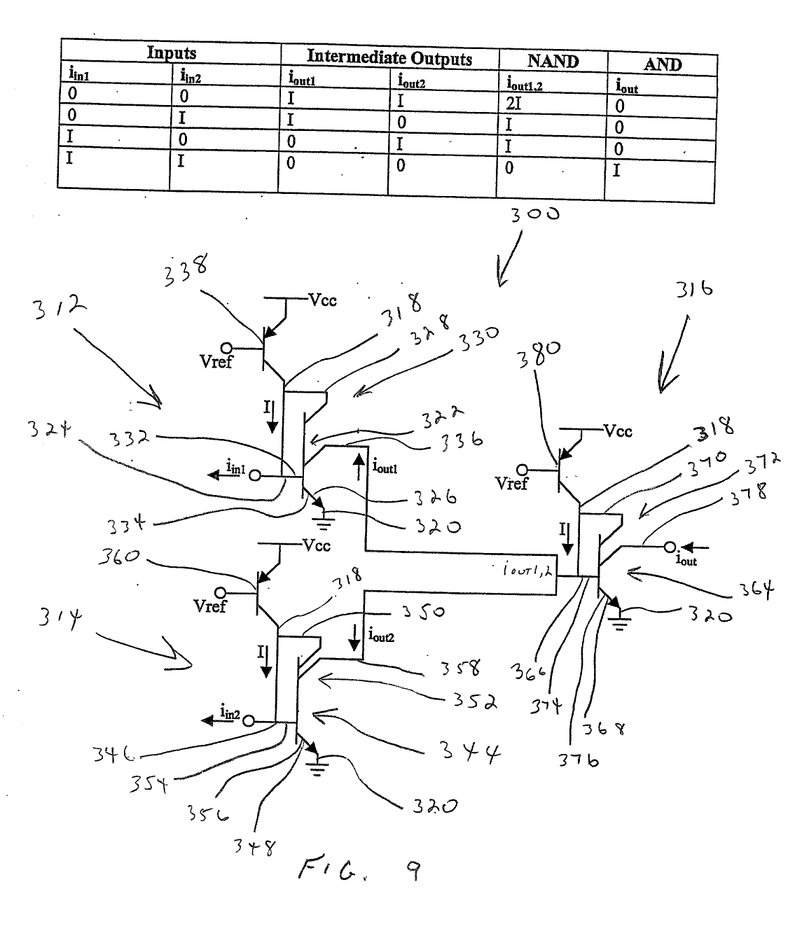

There is shown in FIG. 9, a schematic diagram of a further embodiment of an integrated NAND/AND circuit 300. The integrated NAND/AND function circuit 300 comprises a first integrated sub circuit 312, a second integrated sub circuit 314 and a third integrated sub circuit 316. It should be recognized that the previously described inverter circuit 100 is the basic building block for sub circuits 312, 314 and 316. The first 312, second 314 and third integrated sub circuit 316 have a first power line 318 and a second power line 320.

The first integrated sub circuit 312 comprises a first Bipolar input transistor 322. The first Bipolar input transistor 322 has a first base 324, a first emitter 326 and a first collector 328. The first integrated sub circuit 312 further comprises a second Bipolar output transistor 330. The second Bipolar output transistor 330 has a second base 332, a second emitter 334 and a second collector 336. The first integrated sub circuit 312 includes a first constant current source 338. The first base 324 is connected to a digital input terminal iᵢₙ₁. The second base 332 is connected to the first collector 328. The second collector 336 is connected to a digital output terminal iₒᵤₜ₁. The first collector 328 is coupled to the first constant current source 338 through the first power line 318. The first collector 328 is connected to the digital input terminal iᵢₙ₁.

The second integrated sub circuit 314 comprises a third Bipolar input transistor 344. The third Bipolar input transistor 344 has a third base 346, a third emitter 348 and a third collector 350. The second integrated circuit further comprises a fourth Bipolar output transistor 352. The fourth Bipolar output transistor 352 has a fourth base 354, a fourth emitter 356 and a fourth collector 358. The second integrated sub circuit 314 includes a second constant current source 360. The third base 346 is connected to a digital input terminal iᵢₙ₂. The fourth base 354 is connected to the third collector 350. The fourth collector 358 is connected to a digital output terminal iₒᵤₜ₂. The third collector 350 is coupled to the second constant current source 360 through the first power line 318. The third collector 350 is connected to the digital input terminal iᵢₙ₂.

The third integrated sub circuit 316 comprises a fifth Bipolar input transistor 364. The fifth Bipolar transistor has a fifth base 366, a fifth emitter 368 and a fifth collector 370. The third integrated sub circuit 316 further comprises a sixth Bipolar output transistor 372 having a sixth base 374, a sixth emitter 376 and a sixth collector 378. The third integrated sub circuit 316 includes a third constant current source 380. The first 326, second 334, third 348, fourth 356, fifth 368 and sixth emitters 376 are coupled to the second power line 320. The fifth base 366 is connected to a digital output terminal i_{out1, 2}. The sixth base 374 is connected to the fifth collector 370. The sixth collector 378 is connected to a digital output terminal iₒᵤₜ. The fifth collector 370 is coupled to the third constant current source 380 through the first power line 318. The fifth collector 370 is connected to the digital output terminal i_{out1, 2}. The digital output terminal i_{out1, 2} is connected to digital output terminal iₒᵤₜ₁. The digital output terminal i_{out1, 2} is connected to digital output terminal iₒᵤₜ₂.

No transistor, other than the first input transistor 322 and second output transistor 330, is coupled between the input terminal iᵢₙ₁ and output terminal iₒᵤₜ₁. No transistor, other than the third input transistor 344 and fourth output transistor 352, is coupled between said input terminal iᵢₙ₂ and output terminal iₒᵤₜ₂. No transistor other than the fifth input transistor 364 and sixth output transistor 372 is coupled between said output terminal i_{out1, 2} and output terminal iₒᵤₜ. Individual currents at terminals iᵢₙ₁, iᵢₙ₂, iₒᵤₜ₁ and iₒᵤₜ₂ are logically related to a current at terminal i_{out1, 2} in accordance with a NAND function. Individual currents at terminals iᵢₙ₁, iᵢₙ₂, iₒᵤₜ₁, and iₒᵤₜ₂ are logically related to a current at terminal iₒᵤₜ in accordance with an AND function. Operation of the Bipolar NAND/AND circuit is essentially identical to that of the operation of the FET NAND/AND function circuit 200 described above.

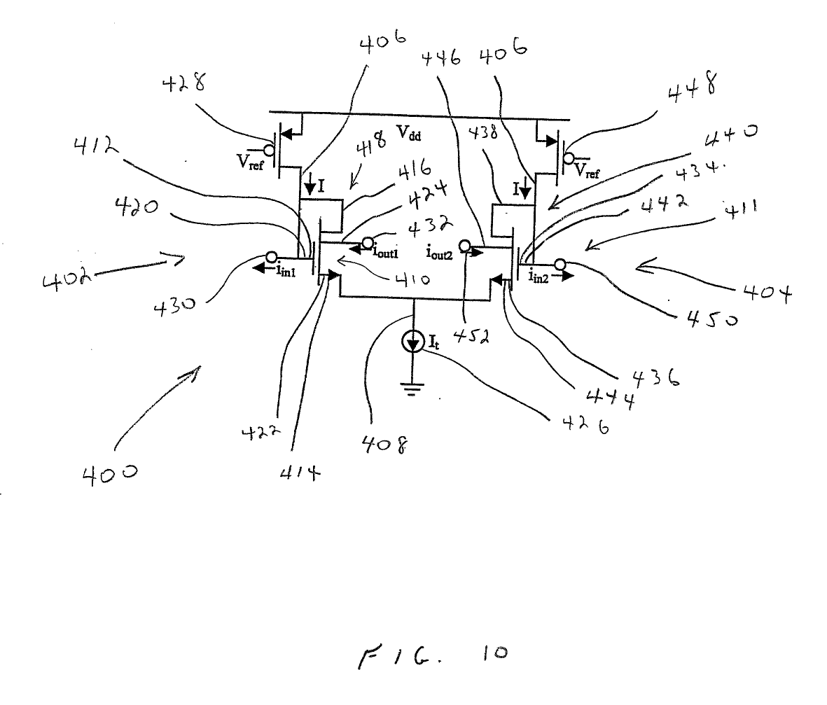

There is shown in FIG. 10, a schematic diagram of a further embodiment of an integrated differential circuit 400. The differential circuit 400 comprises a first integrated sub circuit 402 and second integrated sub circuit 404. It should be recognized that the previously described inverter circuit 10 is the basic building block for sub circuits 402 and 404. The first 402 and second integrated sub circuits 404 have a first power line 406 and second power line 408.

The first integrated sub circuit 404 comprises a first FET transistor 410 having a first gate 412, a first source 414 and a first drain 416. The first integrated sub circuit 404 further comprises a second FET transistor 418 having a second gate 420, a second source 422 and a second drain 424. The first integrated sub circuit 404 includes first 426 and second constant current sources 428. The first 414 and second sources 422 are coupled to the first constant current source 426 through the second power line 408. The first gate 412 is connected to a first digital input terminal 430 and the second gate 420 is connected to the first drain 416. The second drain 424 is connected to a first digital output terminal 432 and the first drain 416 is coupled to the second constant current source 428 through the first power line 406. The first drain 416 is connected to the first digital input terminal 430.

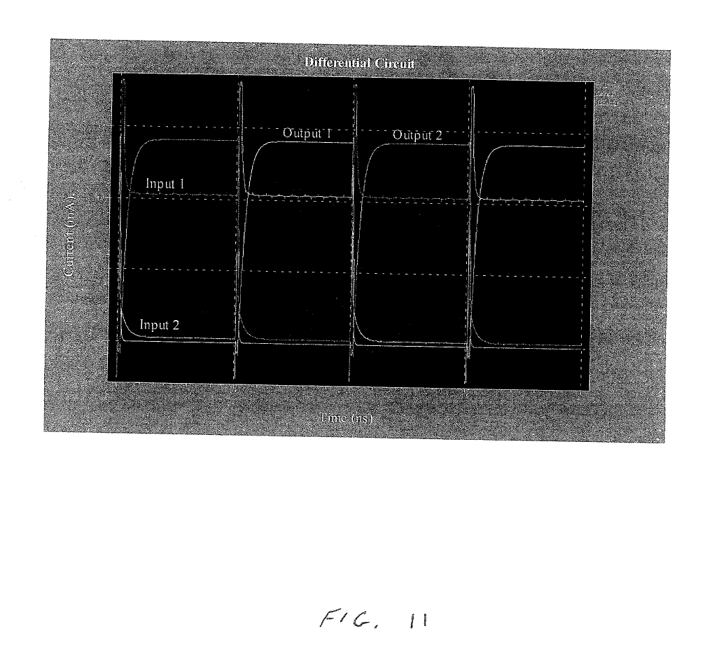

The second integrated sub circuit 410 comprises a third FET transistor 411 having a third gate 434, a third source 436 and a third drain 438. The second integrated sub circuit 410 further comprises a fourth FET transistor 440 having a fourth gate 442, a fourth source 444 and a fourth drain 446. The second integrated circuit 410 includes a third constant current source 448. The third 436 and fourth sources 444 are coupled to the first constant current source 426 through the second power line 408. The third gate 434 is connected to a second digital input terminal 450 and the fourth gate 442 is connected to the third drain 438. The fourth drain 446 is connected to a second digital output terminal 452 and the third drain 438 is coupled to the third constant current source 448 through the first power line 406. The third drain 438 is connected to the second digital input terminal 450. A fifth FET transistor comprises the second constant current source 428. A sixth FET transistor comprises the third constant current source 448. No transistor other than the first 410 and second transistors 418 is coupled between the first input terminal 430 and the first output terminal 432. No transistor other than the third 411 and fourth transistors 440 is coupled between said second input terminal 450 and the second output terminal 452. The differential inverter circuit configuration is useful in cases where a differential current mode signal is available. Here the sub circuits 402 and 404 can be considered as two “composite FET transistors” with better frequency response. The differential input currents to the sub circuits 402 and 406 are inverted and the differential outputs are available from the drains of FET transistors 418 and 440. FIG. 11 shows the differential behavior of the circuits.

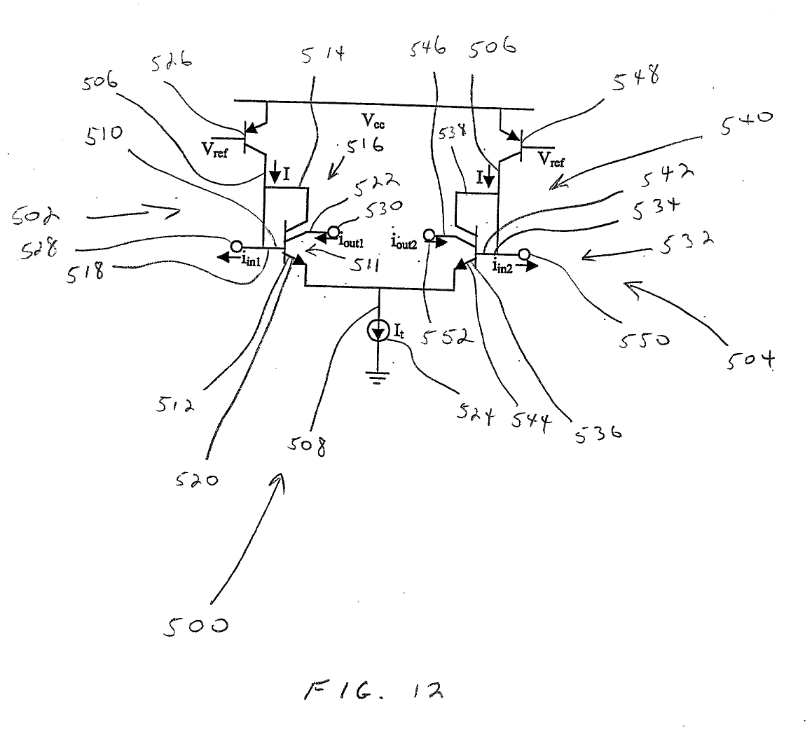

There is shown in FIG. 12, a schematic diagram of a sixth preferred embodiment of an integrated differential circuit 500. The differential circuit 500 comprises a first integrated sub circuit 502 and second integrated sub circuit 504. It should be recognized that the previously described inverter circuit 100 is the basic building block for sub circuits 502 and 504. The first 502 and second integrated sub circuits 504 have a first power line 506 and a second power line 508. The first integrated sub circuit 502 comprises a first Bipolar transistor 511 having a first base 510, a first emitter 512 and a first collector 514. The first integrated sub circuit 502 further comprises a second Bipolar transistor 516 having a second base 518, a second emitter 520 and a second collector 522. The first integrated sub circuit 502 includes first 524 and second constant current sources 526. The first 512 and second emitters 520 are coupled to the first constant current source 524 through the second power line 508. The first base 510 is connected to a first digital input terminal 528 and the second base 518 is connected to the first collector 514. The second collector 522 is connected to a first digital output terminal 530 and the first collector 514 is coupled to the second constant current source 526 through the first power line 506. The first collector 514 is connected to the first digital input terminal 528.

The second integrated sub circuit 504 comprises a third Bipolar transistor 532 having a third base 534, a third emitter 536 and a third collector 538. The second integrated sub circuit 504 further comprises a fourth Bipolar transistor 540 having a fourth base 542, a fourth emitter 544 and a fourth collector 546. The second integrated sub circuit 504 includes a third constant current source 548. The third 536 and fourth emitters 544 are coupled to the first constant current source 524 through the second power line 508. The third base 534 is connected to a second digital input terminal 550 and the fourth base 542 is connected to the third collector 538. The fourth collector 546 is connected to a second digital output terminal 552 and the third collector 538 is coupled to the third constant current source 548 through the first power line 506. The third collector 538 is connected to the second digital input terminal 550. A fifth Bipolar transistor comprises the second constant current source 526 and a sixth Bipolar transistor comprises the third constant current source 548.

No transistor other than the first 511 and second transistors 516 is coupled between the first input terminal 528 and the first output terminal 530. No transistor other than the third 532 and fourth transistors 540 is coupled between the second input terminal 550 and the second output terminal 552. Operation of the Bipolar differential circuit 500 circuit is essentially identical to that of the operation of the FET differential circuit 400 described above.

While the present invention has been disclosed with reference to certain preferred embodiments, numerous modifications, alterations, and changes to the described embodiments are possible without departing from the spirit and scope of the present invention, as defined in the appended claims. Accordingly, it is intended that the present invention not be limited to the described embodiments, but that it have the full scope defined by the language of the following claims, and equivalents thereof.

What is claimed:

1. An integrated inverter circuit comprising:
a FET input transistor having a gate, a source and a drain;
a FET output transistor having a gate, a source and a drain;
first and second power lines;
a constant current source;
the sources of the input and output transistors coupled to the second power line;
the gate of the input transistor being connected to a digital input terminal;
the gate of the output transistor being connected to the drain of the input transistor;
the drain of the output transistor being connected to a digital output terminal;
the drain of the input transistor being coupled to the constant current source through the first power line;
the drain of the input transistor being connected to the digital input terminal; and
wherein no transistor other than said input and output transistors is coupled between said input and output terminals.

2. The integrated inverter circuit according to claim 1, wherein the FET input transistor is merged with the FET output transistor.

3. An integrated inverter circuit comprising:
a Bipolar input transistor having a base, an emitter and a collector;
a Bipolar output transistor having a base, an emitter and a collector;
first and second power lines;
a constant current source;
the emitters of the input and output transistors being coupled to the second power line;
the base of the input transistor being connected to a digital input terminal;
the base of the output transistor being connected to the collector of the input transistor;
the collector of the output transistor being connected to a digital output terminal;
the collector of the input transistor being coupled to the first power line through the constant current source;
the collector of the input transistor being connected to the digital input terminal; and
wherein no transistor other than said input and output transistors is coupled between said input and output terminals.

4. The integrated inverter circuit according to claim 3, wherein the Bipolar input transistor is merged with the Bipolar output transistor.

5. An integrated NAND/AND circuit comprising:
first, second and third integrated sub circuits, the first, second and third integrated sub circuits having first and second power lines;
the first integrated sub circuit comprising;
a first FET input transistor having a first gate, a first source and a first drain;
a second FET output transistor having a second gate, a second source and a second drain;
a first constant current source;
the first gate being connected to a digital input terminal iᵢₙ₁;
the second gate being connected to the first drain;
the second drain being connected to a digital output terminal iₒᵤₜ₁;
the first drain being coupled to the first constant current source through the first power line;
the first drain being connected to the digital input terminal iᵢₙ₁;
the second integrated sub circuit comprising;
a third FET input transistor having a third gate, a third source and a third drain;
a fourth FET output transistor having a fourth gate, a fourth source and a fourth drain;
a second constant current source;
the third gate being connected to a digital input terminal iᵢₙ₂;
the fourth gate being connected to the third drain;
the fourth drain being connected to a digital output terminal iₒᵤₜ₂;
the third drain being coupled to the second constant current source through the first power line;
the third drain being connected to the digital input terminal iᵢₙ₂;
the third integrated sub circuit comprising;
a fifth FET input transistor having a fifth gate, a fifth source and a fifth drain;
a sixth FET output transistor having a sixth gate, a sixth source and a sixth drain;
a third constant current source;
the first, second, third, fourth, fifth and sixth sources being coupled to the second power line;
the fifth gate being connected to a digital output terminal i_{out1, 2};
the sixth gate being connected to the fifth drain;
the sixth drain being connected to a digital output terminal iₒᵤₜ;
the fifth drain being coupled to the third constant current source through the first power line;
the fifth drain being connected to the digital output terminal i_{out1, 2};
the digital output terminal i_{out1, 2} being connected to digital output terminal iₒᵤₜ₁;
the digital output terminal i_{out1, 2} being connected to digital output terminal iₒᵤₜ₂,
wherein no transistor other than said first input and second output transistors is coupled between said input terminal iᵢₙ₁ and output terminal iₒᵤₜ₁;
wherein no transistor other than said third input and fourth output transistors is coupled between said input terminal iᵢₙ₂ and output terminal iₒᵤₜ₂;
wherein no transistor other than said fifth input and sixth output transistors is coupled between said output terminal i_{out1, 2} and output terminal iₒᵤₜ;
wherein individual currents at terminals iᵢₙ₁, iᵢₙ₂, iₒᵤₜ₁ and iₒᵤₜ₂ are logically related to a current at terminal i_{out1, 2} in accordance with a NAND function; and
wherein individual currents at terminals iᵢₙ₁, iᵢₙ₂, iₒᵤₜ₁ and iₒᵤₜ₂ are logically related to a current at terminal iₒᵤₜ in accordance with an AND function.

6. The integrated NAND/AND circuit according to claim 5, wherein the first FET input transistor is merged with the second FET output transistor.

7. The integrated NAND/AND circuit according to claim 5, wherein the third FET input transistor is merged with the fourth FET output transistor.

8. The integrated NAND/AND circuit according to claim 5, wherein the fifth FET input transistor is merged with the sixth FET output transistor.

9. An integrated NAND/AND circuit comprising:
first, second and third integrated sub circuits, the first, second and third integrated sub circuits having first and second power lines;
the first integrated sub circuit comprising;
a first Bipolar input transistor having a first base, a first emitter and a first collector;
a second Bipolar output transistor having a second base, a second emitter and a second collector;
a first constant current source;
the first base being connected to a digital input terminal iᵢₙ₁;
the second base being connected to the first drain;
the second collector being connected to a digital output terminal iₒᵤₜ₁;
the first collector being coupled to the first constant current source through the first power line;
the first collector being connected to the digital input terminal iᵢₙ₁;
the second integrated sub circuit comprising;
a third Bipolar input transistor having a third base, a third emitter and a third collector;
a fourth Bipolar output transistor having a fourth base, a fourth emitter and a fourth collector;
a second constant current source;
the third base being connected to a digital input terminal iᵢₙ₂;
the fourth base being connected to the third drain;
the fourth collector being connected to a digital output terminal iₒᵤₜ₂;
the third collector being coupled to the second constant current source through the first power line;
the third collector being connected to the digital input terminal iᵢₙ₂;
the third integrated sub circuit comprising;
a fifth Bipolar input transistor having a fifth base, a fifth emitter and a fifth collector;
a sixth Bipolar output transistor having a sixth base, a sixth emitter and a sixth collector;
a third constant current source;
the first, second, third, fourth, fifth and sixth emitters being coupled to the second power line;
the fifth base being connected to a digital output terminal i_{out1, 2};
the sixth base being connected to the fifth drain;
the sixth collector being connected to a digital output terminal iₒᵤₜ;
the fifth collector being coupled to the third constant current source through the first power line;
the fifth collector being connected to the digital output terminal i_{out1, 2};
the digital output terminal i_{out1, 2} being connected to digital output terminal iₒᵤₜ₁,
the digital output terminal i_{out1, 2} being connected to digital output terminal iₒᵤₜ₂,
wherein no transistor other than said first input and second output transistors is coupled between said input terminal iᵢₙ₁ and output terminal iₒᵤₜ₁;
wherein no transistor other than said third input and fourth output transistors is coupled between said input terminal iᵢₙ₂ and output terminal iₒᵤₜ₂;
wherein no transistor other than said fifth input and sixth output transistors is coupled between said output terminal i_{out1, 2} and output terminal iₒᵤₜ;
wherein individual currents at terminals iᵢₙ₁, iᵢₙ₂, iₒᵤₜ₁ and iₒᵤₜ₂ are logically related to a current at terminal i_{out1, 2} in accordance with a NAND function; and
wherein individual currents at terminals iᵢₙ₁, iᵢₙ₂, iₒᵤₜ₁ and iₒᵤₜ₂ are logically related to a current at terminal iₒᵤₜ in accordance with an AND function.

10. The integrated NAND/AND circuit according to claim 9, wherein the first Bipolar input transistor is merged with the second Bipolar output transistor.

11. The integrated NAND/AND circuit according to claim 9, wherein the third Bipolar input transistor is merged with the fourth Bipolar output transistor.

12. The integrated NAND/AND circuit according to claim 9, wherein the fifth Bipolar input transistor is merged with the sixth Bipolar output transistor.

13. An integrated differential circuit comprising:
first and second integrated sub circuits, the first and second integrated sub circuits having first and second power lines;
the first integrated sub circuit comprising;
a first FET transistor having a first gate, a first source and a first drain;
a second FET transistor having a second gate, a second source and a second drain;
first and second constant current sources;
the first and second sources being coupled to the first constant current source through the second power line;
the first gate being connected to a first digital input terminal;
the second gate being connected to the first drain;
the second drain being connected to a first digital output terminal;
the first drain being coupled to the second constant current source through the first power line;
the first drain being connected to the first digital input terminal;
the second integrated sub circuit comprising;
a third FET transistor having a third gate, a third source and a third drain;
a fourth FET transistor having a fourth gate, a fourth source and a fourth drain;
a third constant current source;
the third and fourth sources coupled to the first constant current source through the second power line;
the third gate being connected to a second digital input terminal;
the fourth gate being connected to the third drain;
the fourth drain being connected to a second digital output terminal;
the third drain being coupled to the third constant current source through the first power line;
the third drain being connected to the second digital input terminal;
wherein a fifth FET transistor comprises the second constant current source;
wherein a sixth FET transistor comprises the third constant current source;
wherein no transistor other than said first and second transistors is coupled between said first input terminal and said first output terminal; and
wherein no transistor other than said third and fourth transistors is coupled between said second input terminal and said second output terminal.

14. The integrated differential circuit according to claim 13, wherein the first FET transistor is merged with the second FET transistor.

15. The integrated differential circuit according to claim 13, wherein the third FET transistor is merged with the fourth FET transistor.

16. An integrated differential circuit comprising:
first and second integrated sub circuits, the first and second integrated sub circuits having first and second power lines;
the first integrated sub circuit comprising;
a first Bipolar transistor having a first base, a first emitter and a first collector;
a second Bipolar transistor having a second base, a second emitter and a second collector;
first and second constant current sources;
the first and second emitters being coupled to the first constant current source through the second power line;
the first base being connected to a first digital input terminal;
the second base being connected to the first collector;
the second collector being connected to a first digital output terminal;
the first collector being coupled to the second constant current source through the first power line;
the first collector being connected to the first digital input terminal;
the second integrated sub circuit comprising;
a third Bipolar transistor having a third base, a third emitter and a third collector;
a fourth Bipolar transistor having a fourth base, a fourth emitter and a fourth collector;
a third constant current source;
the third and fourth emitters coupled to the first constant current source through the second power line;
the third base being connected to a second digital input terminal;
the fourth base being connected to the third collector;
the fourth collector being connected to a second digital output terminal;
the third collector being coupled to the third constant current source through the first power line;
the third collector being connected to the second digital input terminal;
wherein a fifth Bipolar transistor comprises the second constant current source;
wherein a sixth Bipolar transistor comprises the third constant current source;
wherein no transistor other than said first and second transistors is coupled between said first input terminal and said first output terminal; and
wherein no transistor other than said third and fourth transistors is coupled between said second input terminal and said second output terminal.

17. The integrated differential circuit according to claim 16, wherein the first FET transistor is merged with the second FET transistor.

18. The integrated differential circuit according to claim 16, wherein the third FET transistor is merged with the fourth FET transistor.
